(19) United States
(12) Patent Application Publication
(10) Pub. No.: US 2003/0203546 A1
(43) Pub. Date: Oct. 30, 2003

(54) SOI transistor element having an improved backside contact and method of forming the same

(76) Inventors: Gert Burbach, Dresden (DE); Massud Aminpur, Dresden (DE)

Correspondence Address: J. Mike Amerson, Williams, Morgan & Amerson, P.C., Suite 250, 7676 Hillmont, Houston, TX, 77040, US

(21) Appl. No.: 10/284,114

(22) Filed: Oct. 30, 2002

(30) Foreign Application Priority Data
Apr. 29, 2002 (DE) 102 19 107.7

(51) Int. Cl. H01L 21/339; H01L 21/00; H01L 21/84; H01L 21/76

(52) U.S. Cl. 438/151; 438/405

(57) ABSTRACT

The present invention relates to a method of forming contacts of semiconductor devices manufactured on silicon-on-oxide (SOI) wafers. According to the method of the present invention, a heavily doped region is formed in the backside silicon layer during the manufacturing process and a backside contact to the heavily doped region is provided at the end of the manufacturing process. The backside contact exhibits nearly ohmic characteristics avoiding the drawbacks arising from Schottky backside contacts as formed with the usual prior art methods. Moreover, a transistor including a backside contact with an ohmic substrate contact junction is disclosed.

### BACKGROUND OF THE INVENTION

1. Field of the Invention

The present invention relates to the field of fabrication of integrated circuits, and, more particularly, to silicon-on-insulator (SOI) transistor elements having a backside contact and a method of forming electrical contacts for integrated circuits fabricated on SOI wafers.

2. Description of the Related Art

In recent years, the use of silicon-on-insulator (SOI) wafers for fabricating integrated circuits has increased significantly. In particular, SOI wafers have been revealed as having the potential to improve the performance of CMOS circuits and have become widely used substrates in the manufacture of CMOS devices.

Typically, an SOI wafer comprises an upper and a lower layer of silicon and a dielectric layer sandwiched therebetween. The upper layer is sometimes referred to as the active layer, the lower layer is sometimes referred to as the bulk substrate and the dielectric layer is sometimes referred to as a buried oxide layer (“BOX”).

In the art, several approaches are known for forming SOI wafers. Depending on the approach used, different materials are selected for forming the sandwiched dielectric layer. For instance, when silicon-on-sapphire (SOS) wafers are formed, a layer of pure aluminum oxide is sandwiched between two layers of silicon. Alternatively, the separation by implanted oxygen (SIMOX) approach and/or the wafer bonding (WB) approach can be used for forming SOI wafers wherein silicon dioxide is used as the dielectric material.

When building devices on SOI wafers, small islands of silicon are formed (typically by dry etch techniques) on top of the dielectric layer. Individual devices are then fashioned in the islands and these devices are then interconnected in the conventional way.

There are several advantages offered by the SOI technology. First, circuits fabricated in SOI wafers have reduced parasitic capacitance when compared to bulk wafers that may have an additional epitaxially grown silicon layer. Less capacitance translates into lower power consumption or higher speed. Second, SOI devices have improved radiation-induced single-event upset (SEU) immunity, and thus they are useful for space applications. Third, SOI devices are completely free of latch-up. Finally, the fabrication process on SOI wafers can be simplified by reducing the number of masks by as much as 30%.

However, fabricating semiconductor devices on SOI wafers has the drawback that the lower silicon layer is isolated by the intermediate dielectric layer and cannot be easily connected to the front side of the wafer. However, at least one electrical contact to the lower silicon layer has to be provided since a floating silicon layer under the sandwiched dielectric layer may have an unpredictable impact on the devices fabricated on the wafer.

Several techniques have been proposed in the art for contacting the backside of SOI wafers. For instance, according to a well-known technique, contacts to the backside of SOI wafers can be formed during packaging at the end of the manufacturing process. However, this solution is normally not preferred in view of the high costs involved.

At present, the most common method for forming backside contacts for SOI wafers is the so-called dual-contact approach. In the following, a description will be given with reference to FIGS. 1a-1g of the manner backside contacts for CMOS transistors on SOI wafers are formed according to the prior art dual-contact approach.

In FIGS. 1a-1g, reference 1 relates to an arbitrary section of an SOI substrate on which a CMOS transistor 100 is to be formed. The SOI substrate 1 is comprised of an upper layer of silicon (active layer) la, a layer of insulating material 1b (sometimes referred to as a buried oxide (“BOX”) layer), and a lower layer of silicon (bulk substrate) 1c. In particular, FIG. 1a depicts the situation at the moment during the manufacturing process when the essential parts of the CMOS transistors have been formed and contacts to the lower silicon layer 1c and to the CMOS transistor must still be formed. Accordingly, in FIG. 1a, reference 2 relates to isolation structures, afterwards called shallow trench isolations (STI), which have been previously formed in the upper layer 1a. These isolation structures 2 divide the upper layer 1a of the substrate 1 into two portions on which the PMOS transistor and NMOS transistor are to be formed, respectively. In the particular case depicted in FIG. 1a, the PMOS portion is depicted on the left side of the figure and the NMOS portion is depicted on the right side of the figure. Moreover, in FIGS. 1a-1g, references 3p and 3n relate to the gate polysilicon electrodes of the PMOS and NMOS transistors, respectively. References 4p and 4n relate to oxide side spacers formed on the sidewalls of the gate polysilicon electrodes. References 6p and 6n relate to the gate insulation layers on the PMOS region and the NMOS region, respectively. In FIGS. 1a-1g, references 5p and 5n identify the source and drain regions of the PMOS and NMOS transistors, respectively. Finally, references 8p and 8n relate to metal suicide layers formed on top of the polysilicon gate electrodes 3p and 3n and on the source and drain regions 5p and 5n.

Once the essential parts of the CMOS transistor as depicted in FIG. 1a have been formed, the manufacturing process proceeds with the formation on the wafer 1 of a dielectric stack for the purpose of planarizing the wafer 1. As is apparent from FIGS. 1b-1g, the planarization stack comprises a first dielectric layer 9 and a second dielectric layer 10, which is planarized, after deposition, by chemical mechanical polishing (CMP). The underlying dielectric layer 9 usually comprises silicon oxynitride (SiON) and has two functions. First, it serves as a BARC (buried anti-reflective coating) layer for the critical contact hole lithography. Second, it serves as an etch stop layer allowing the holes for the contacts to the polysilicon gate electrodes 3p, 3n and the source/drain regions 5p, 5n of the transistor to be etched during a common etching step.

After planarization of the dielectric layer 10, a first masking and etching step is used to open a contact hole from the upper surface of the planarized wafer 1 to the lower silicon layer 1c. In particular, as is apparent from FIG. 1c, a first resist layer 11 is deposited on the wafer and patterned so as to expose the portion of the wafer 1 targeted for the backside contact. Subsequently, as depicted in FIG. 1d, the exposed portion of the wafer is etched away so as to form a contact hole 12 from the upper surface of the wafer to the lower silicon layer 1c. During this etching step, the upper dielectric layer 10, the underlying dielectric layer 9, as well as the isolation structure 2 and the upper silicon layer 1a are anisotropically etched.

Once the contact hole 12 has been formed, a second masking and etching step is used to open the contact holes to the metal silicides 8p and 8n on the polysilicon gate electrodes 3p and 3n and the source and drain regions 5p and 5n of the PMOS and NMOS transistors. With an approach similar to that used for opening the backside contact hole 12, a second resist layer 11′ is deposited on the wafer 1 and patterned so as to expose those portions of the wafer 1 targeted for the contacts to the transistors (FIG. 1e). A further etching step is then carried out, as depicted in FIG. 1f, for opening contact holes 12′ from the upper surface of the wafer to the metal silicides 8p and 8n. During the etching step, a stack of two different dielectric materials has to be anisotropically etched, namely the dielectric layer 10 and the underlying layer 9 of SiON. As is apparent from FIG. 1f, the dielectric layer 10 is thicker above the source and drain regions 5p and 5n than above the gate polysilicon electrodes 3p and 3n. Accordingly, the dielectric layer 10 has to be etched to different depths. To this end, the BARC dielectric layer 9 serves as an etch stop allowing contact holes to the polysilicon gate electrodes and to the source and drain regions to be open during a common etching step.

Once all contact holes 12 and 12′ have been opened, all contact holes are filled with tungsten 12″ with a common fill-step, as depicted in FIG. 1g. Finally, the excess tungsten is removed from the wafer surface with a CMP step not depicted in the figures.

The prior art dual-contact approach described above has the drawback that Schottky contacts are formed between the tungsten 12″ and the lower silicon layer 1c. This means that the contacts do not exhibit an ohmic behavior, but instead exhibit non-negligible resistance to the flow of current in either direction through the contact. When backside Schottky contacts or non-ohmic contacts are formed, the performance of the circuit fabricated on the substrate, in particular the performance of high speed circuits, can be negatively affected.

Accordingly, in view of the problems explained above, it would be desirable to provide a method of forming backside contacts on SOI wafers that may solve or reduce one or more of the problems identified above.

### SUMMARY OF THE INVENTION

In general, the present invention is directed to a method allowing the formation of backside contacts on SOI wafers exhibiting a nearly ohmic behavior and a transistor element having a backside contact including a heavily doped silicon region.

In particular, the present invention is based on the consideration that nearly ohmic metal semiconductor contacts can be created by forming and contacting a heavily doped region in the surface of the lower layer of silicon. In fact, the charge transport across a metal semiconductor contact can be indirectly influenced by the doping concentration of the doped region formed in the lower layer of silicon. That is, when doping concentration is low, only carriers that have energies greater than the barrier height can overcome the barrier. In contrast, if the doping concentration exceeds these values, carrier transport becomes dominated by quantum-mechanical tunneling.

Accordingly, starting from this teaching, the method of the present invention allows one to realize nearly ohmic backside contacts on SOI wafers by forming heavily doped regions in the backside silicon layer.

In particular, according to one embodiment, the present invention relates to a method of forming at least one electrical contact on a substrate, wherein the substrate comprises an upper and a lower semiconductor layer and a dielectric layer sandwiched therebetween. The method further comprises masking the substrate with a first protective layer comprising at least one aperture and implanting a dopant material into the lower semiconductor layer through the at least one aperture of the protective layer so as to form at least one doped region in the lower semiconductor layer in correspondence with the at least one aperture of the protective layer. Furthermore, the method comprises forming at least one conductive via that extends through the substrate from the doped regions in the lower semiconductor layer to the upper surface of the substrate.

According to another embodiment, the present invention relates to a method of forming at least one semiconductor device on a substrate, wherein the substrate comprises an upper and a lower semiconductor layer and a first dielectric layer sandwiched therebetween. The method comprises doping the lower semiconductor layer with a dopant material so as to form at least one doped region in the lower semiconductor layer, completing the at least one semiconductor device, depositing at least one second layer of dielectric material on the upper semiconductor layer and planarizing the deposited dielectric material. The method further comprises forming at least one conductive via that extends through the planarized dielectric material, the upper semiconductor layer and the sandwiched dielectric layer from the at least one doped region in the lower semiconductor layer.

In still another embodiment of the present invention there is provided a method of forming at least one field effect transistor on a substrate, wherein the substrate comprises an upper and a lower semiconductor layer and a dielectric layer sandwiched therebetween. The method comprises forming at least one doped region at the upper surface of the lower semiconductor layer, completing the at least one field effect transistor and depositing at least one dielectric planarization layer on the substrate. Additionally, the method comprises forming at least one contacting via from the upper surface of the at least one dielectric planarization layer to the at least one doped region and at least one conductive via from the upper surface of the at least one dielectric planarization layer to the at least one field effect transistor.

According to a further embodiment of the present invention, there is provided a method of forming at least one field effect transistor on a substrate, wherein the substrate comprises an upper and a lower semiconductor layer and a dielectric layer sandwiched therebetween. The method comprises forming a plurality of features above the upper semiconductor layer, the features defining at least one trench above the upper semiconductor layer, forming at least one doped region in a portion of the lower semiconductor layer underneath the at least one trench above the upper semiconductor layer and completing the at least one field effect transistor. The method further comprises depositing at least one dielectric layer above the substrate, planarizing the dielectric layer and forming at least one contacting via that extends from an upper surface of the planarized dielectric layer to the at least one doped region and at least one conductive via that extends from the upper surface of the planarized dielectric layer to the at least one field effect transistor.

In a further illustrative embodiment, the present invention relates to a field effect transistor formed on a substrate comprising at least an upper and a lower semiconductor layer and a dielectric layer sandwiched therebetween. The transistor further comprises at least one doped region in the lower semiconductor layer and at least one electrical contact contacting the at least one doped region of decreased resistance.

### BRIEF DESCRIPTION OF THE DRAWINGS

The invention may be understood by reference to the following description taken in conjunction with the accompanying drawings, in which like reference numerals identify like elements, and in which:

FIGS. 1a-1g represent a typical process sequence of a prior art method for forming contacts on SOI wafers;

FIGS. 2a-2g represent a first process sequence for forming heavily doped regions in SOI wafers according to the method of the present invention; and

FIGS. 3a-3g represent an example of the manner the process sequence depicted in FIGS. 2a-2g can be completed for forming contacts on SOI wafers according to the method of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention is understood to be particularly advantageous when used for forming the contacts of CMOS transistors manufactured on SOI wafers. In particular, the present invention is understood to be especially advantageous when used for forming the backside contacts of CMOS transistors manufactured on SOI wafers. For this reason, examples will be given in the following in which corresponding embodiments of the method of the present invention are utilized for forming backside contacts on SOI wafers on which CMOS transistors are manufactured. However, it has to be noted that the present invention is not limited to the particular case of CMOS transistors manufactured on SOI wafers, but can be used in any other situation in which the realization of backside contacts is required. An integrated circuit may require one or more contacts to the backside of the wafer on which it is manufactured. The present invention is also applicable to these integrated circuits irrespective of the functions performed. For instance, although described with reference to a CMOS transistor, the method of the present invention may also be used for forming backside contacts for NMOS transistors, PMOS transistors and similar field effect transistors.

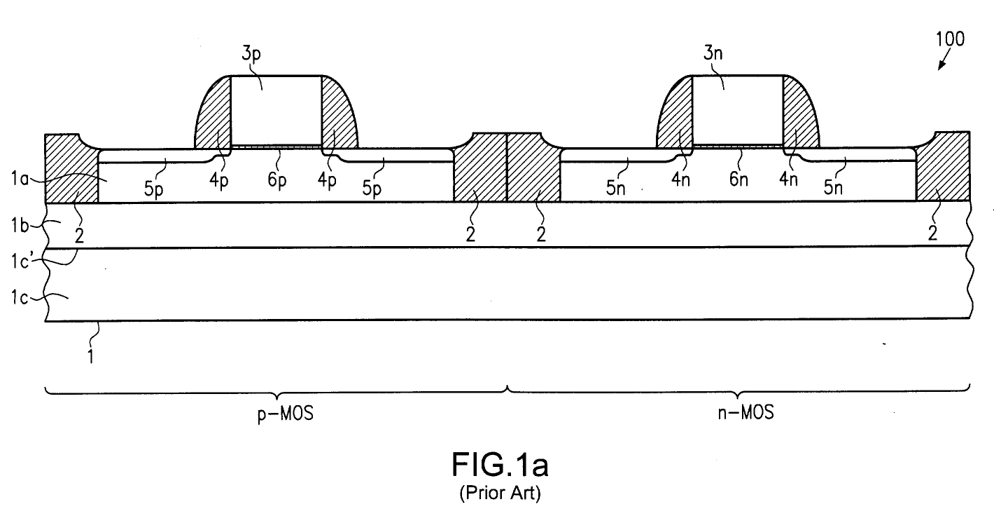

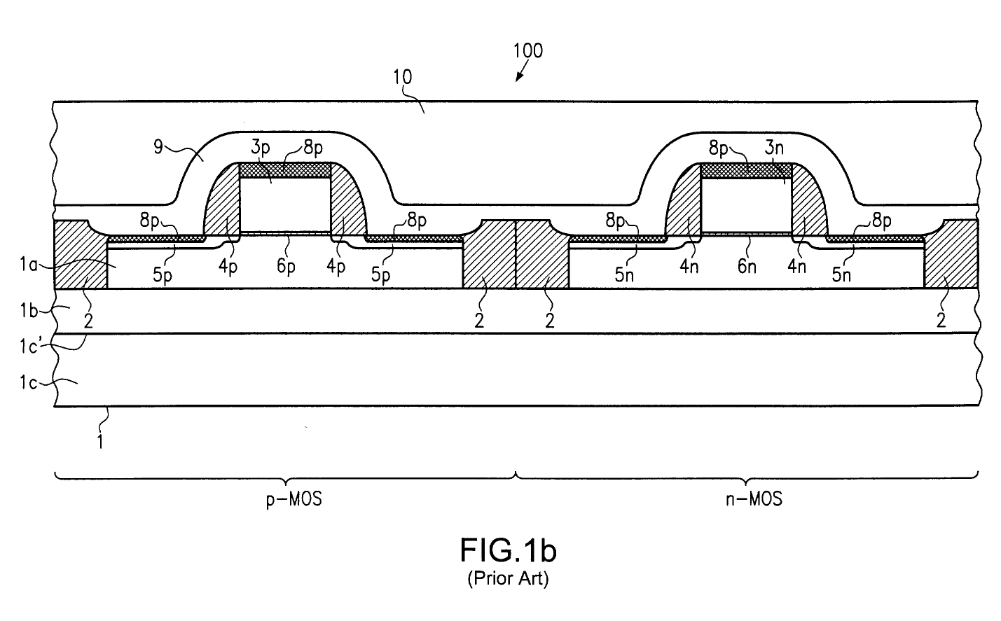

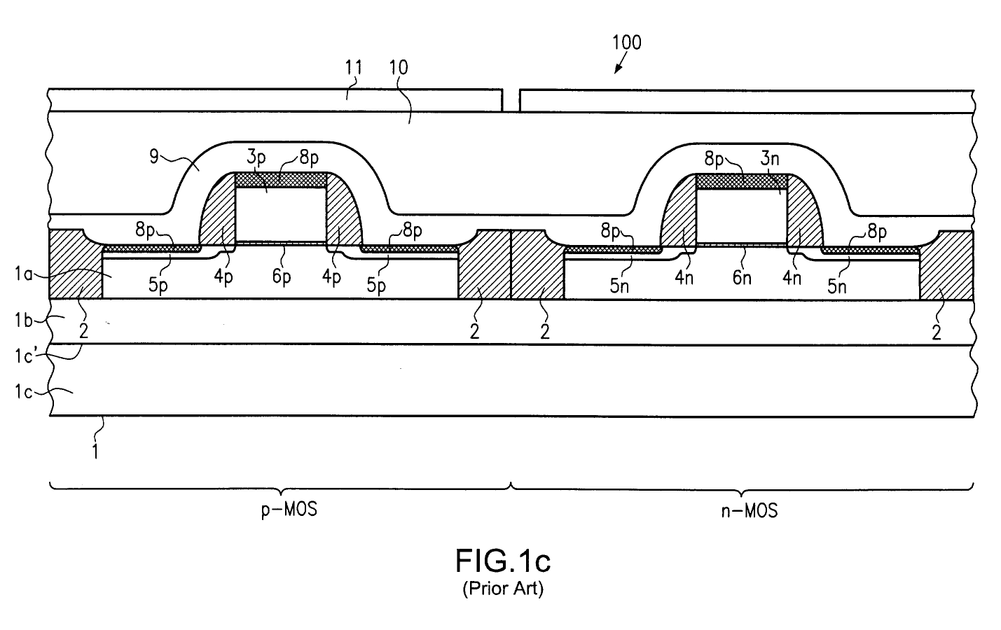

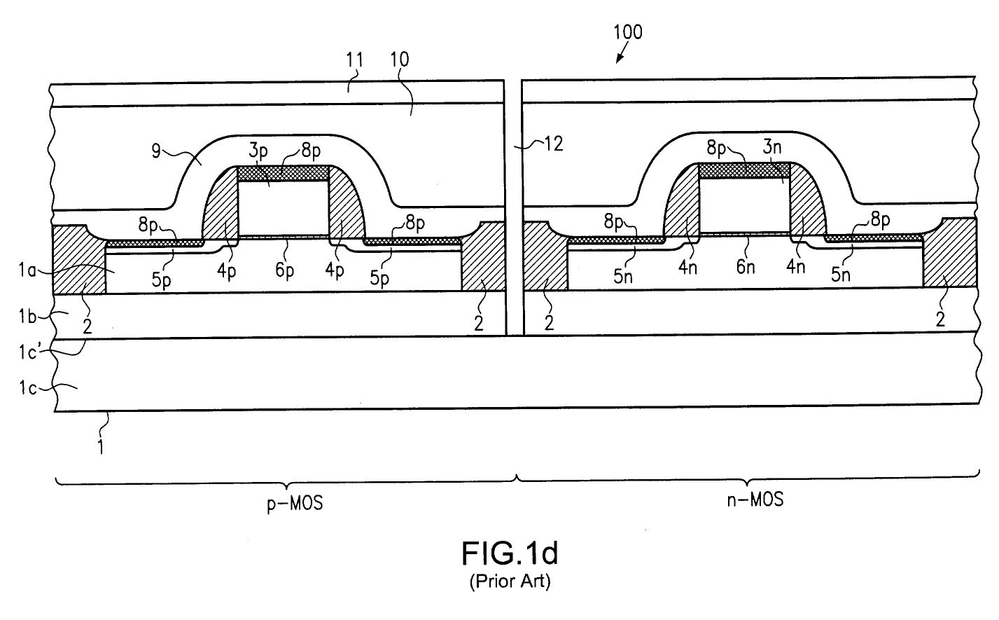

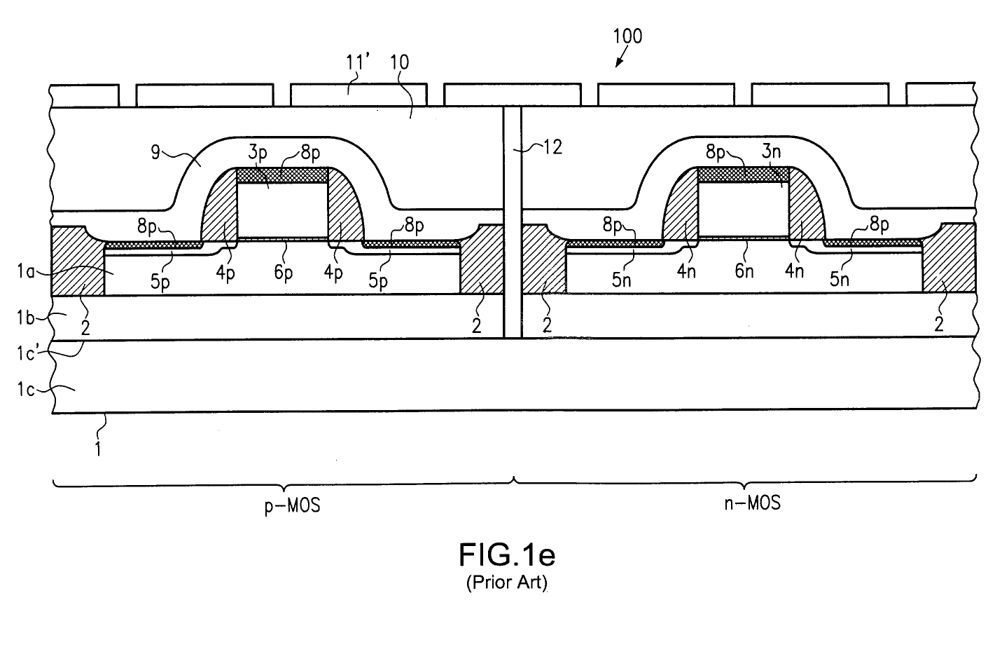

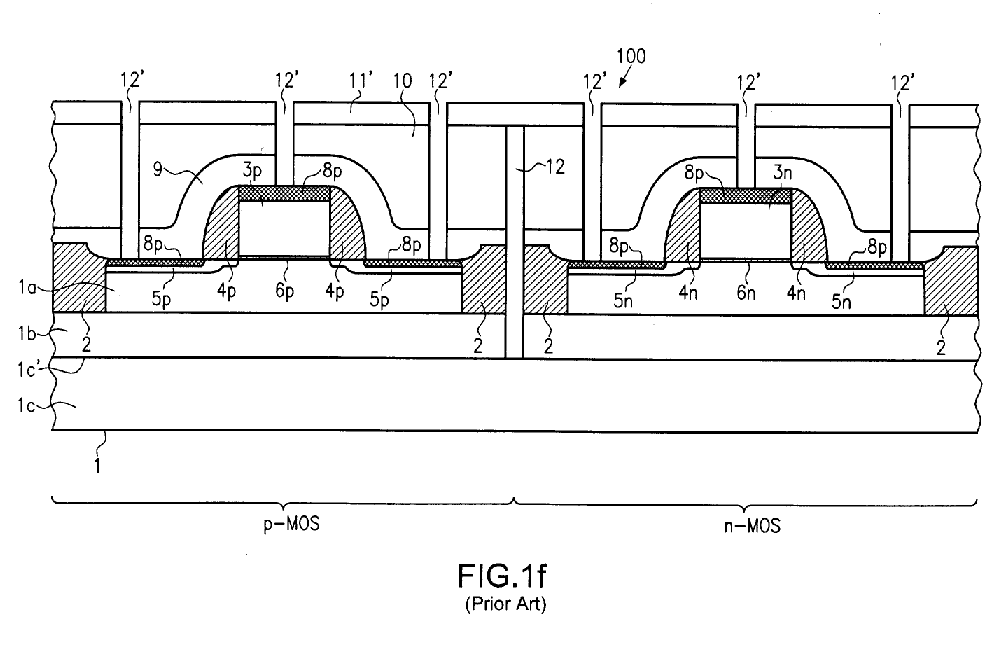

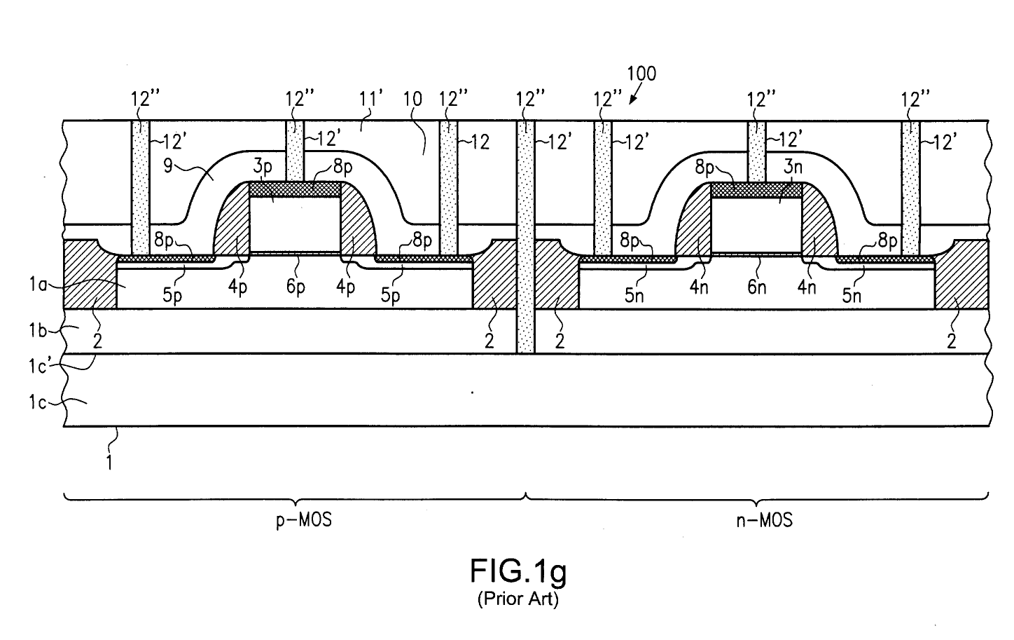

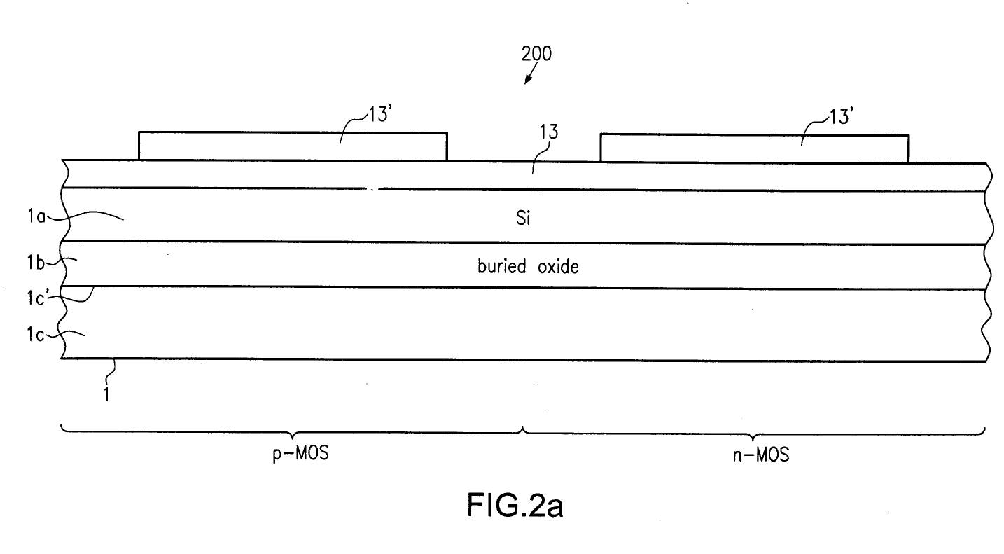

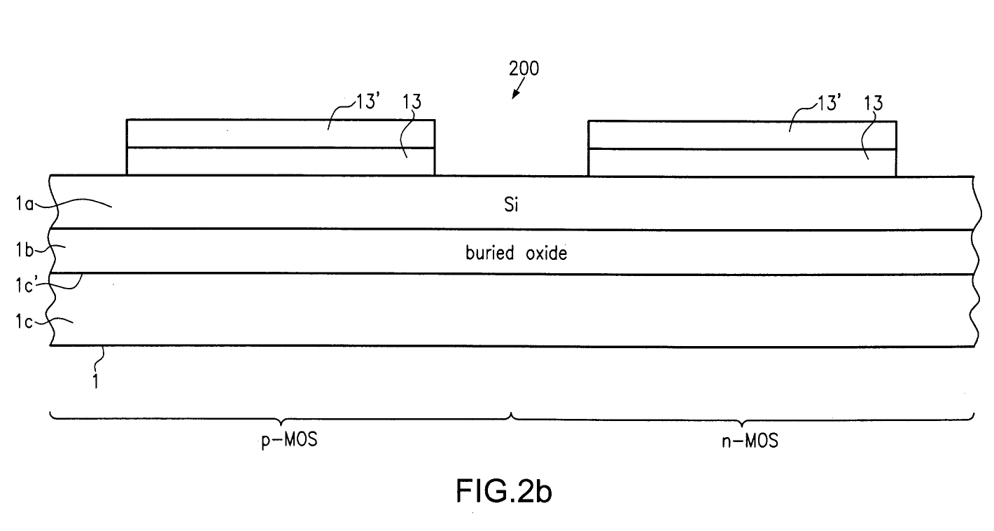

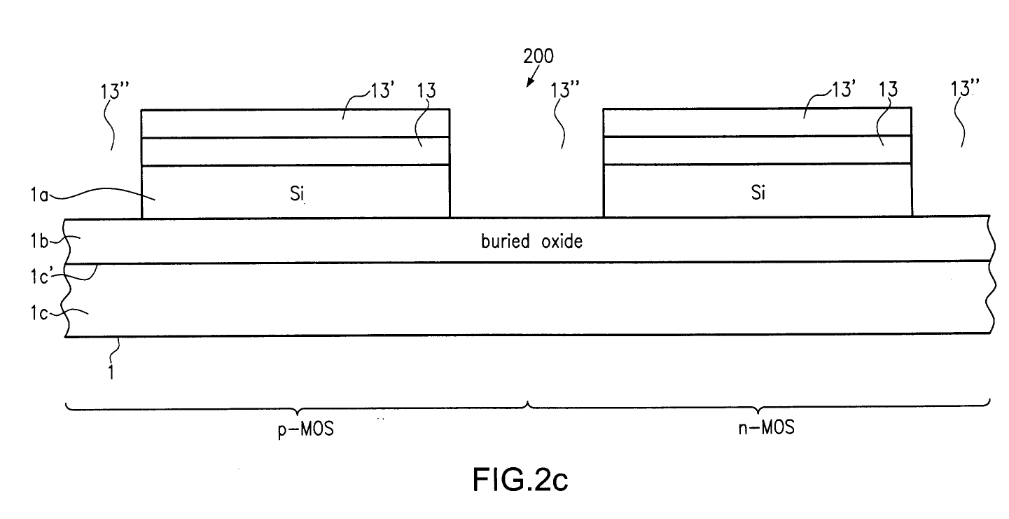

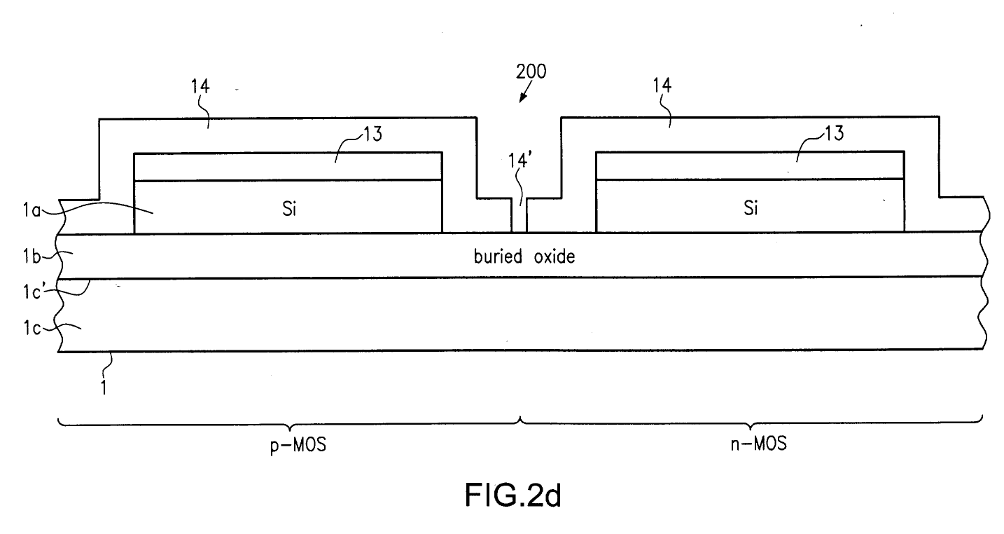

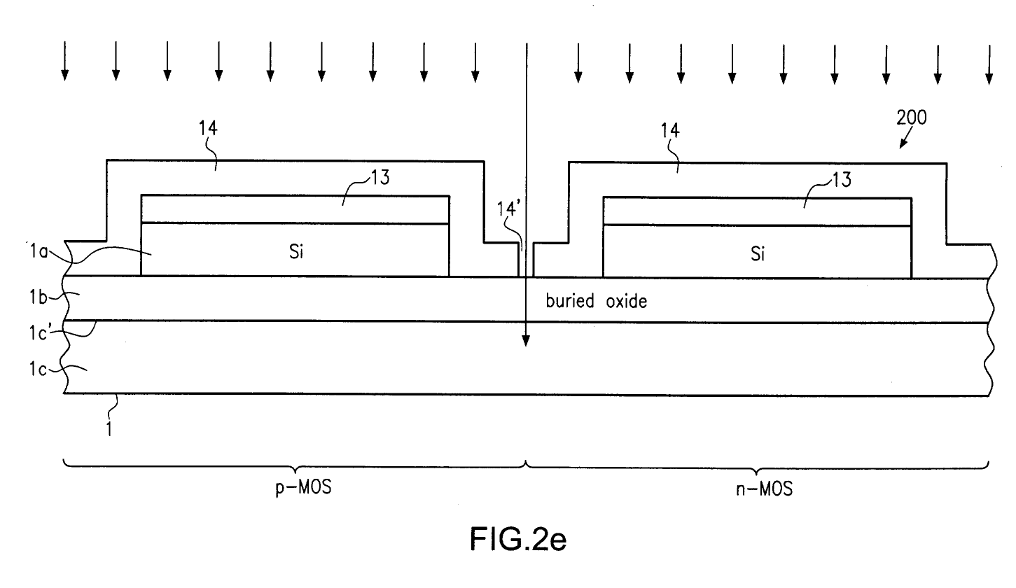

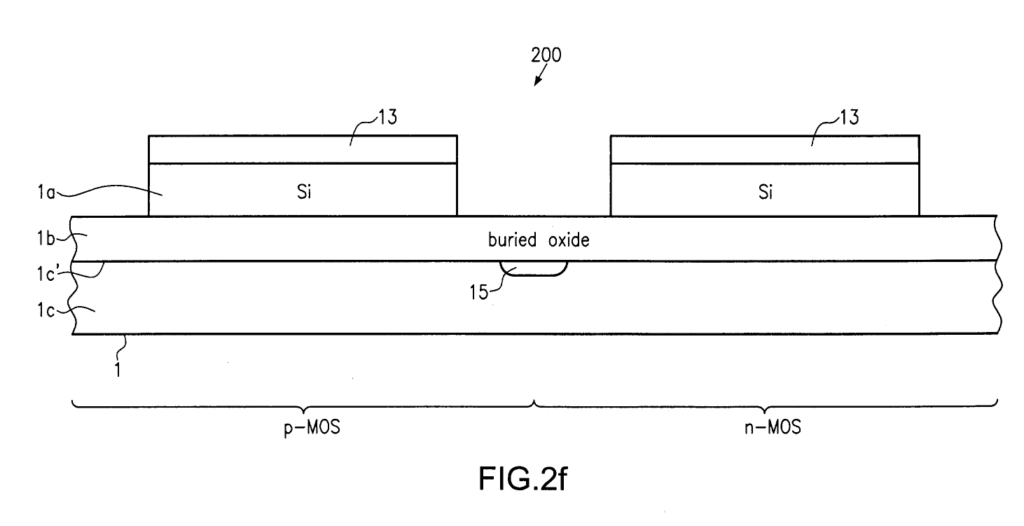

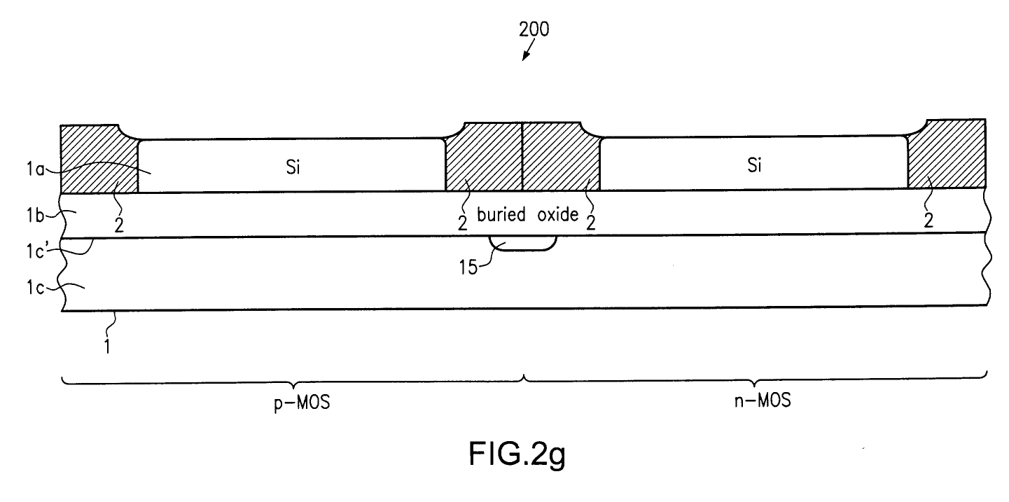

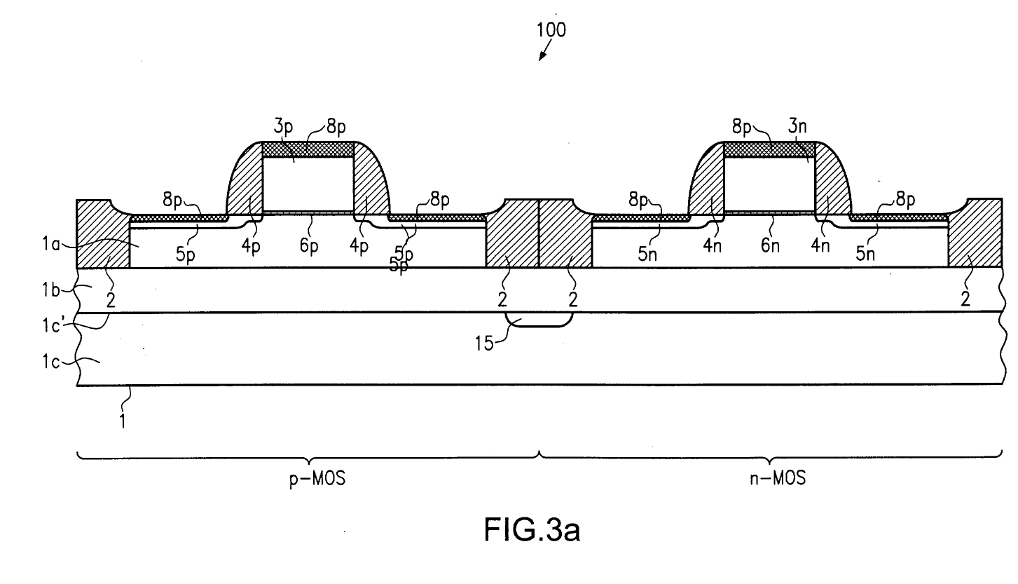

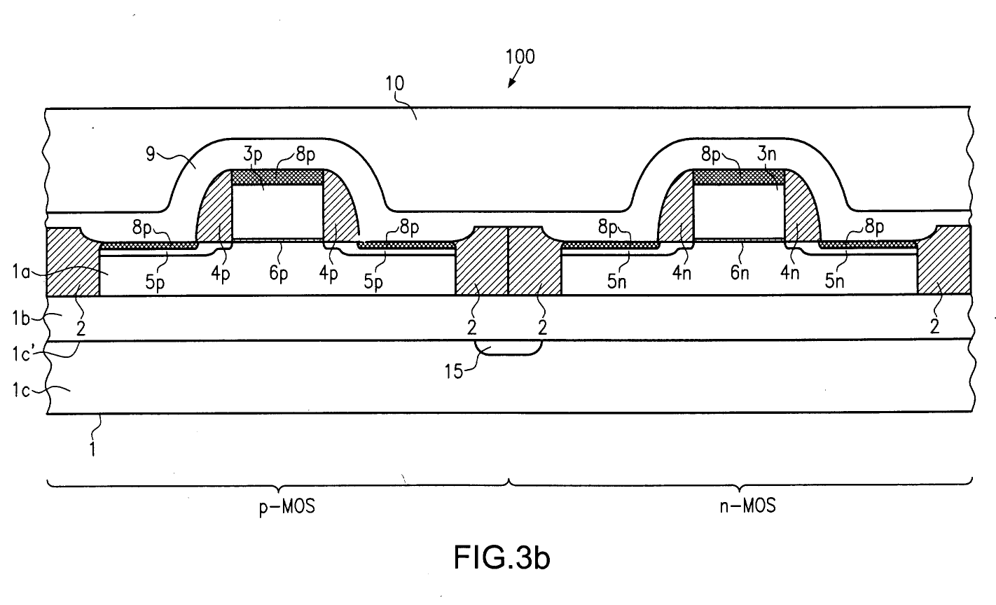

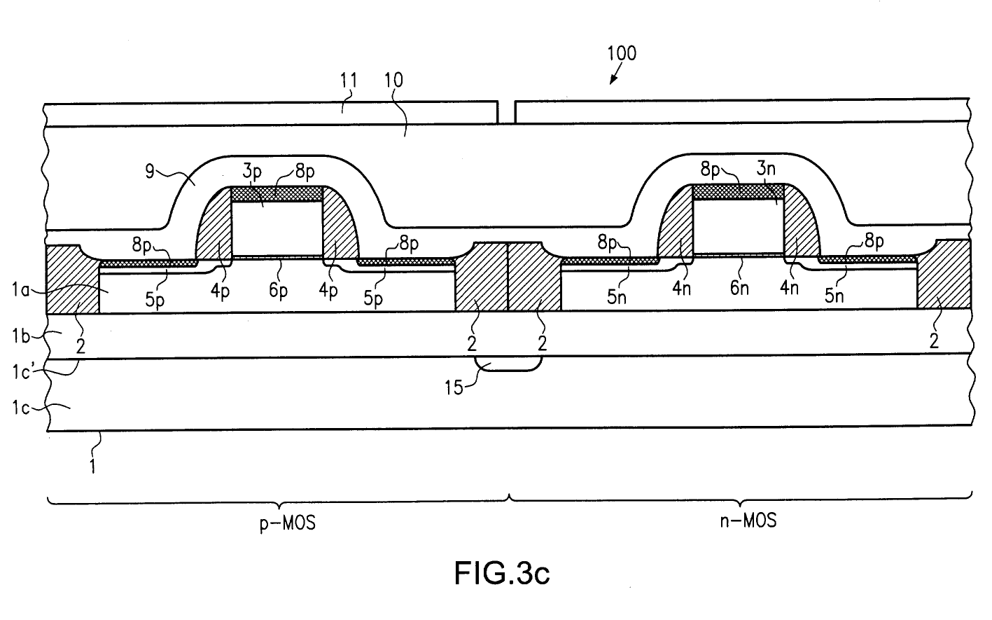

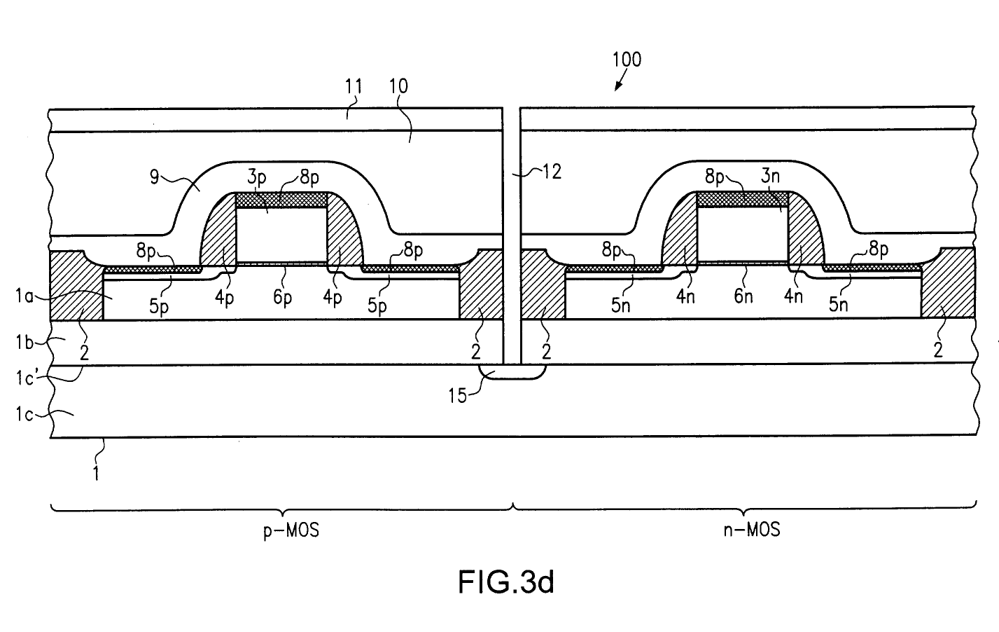

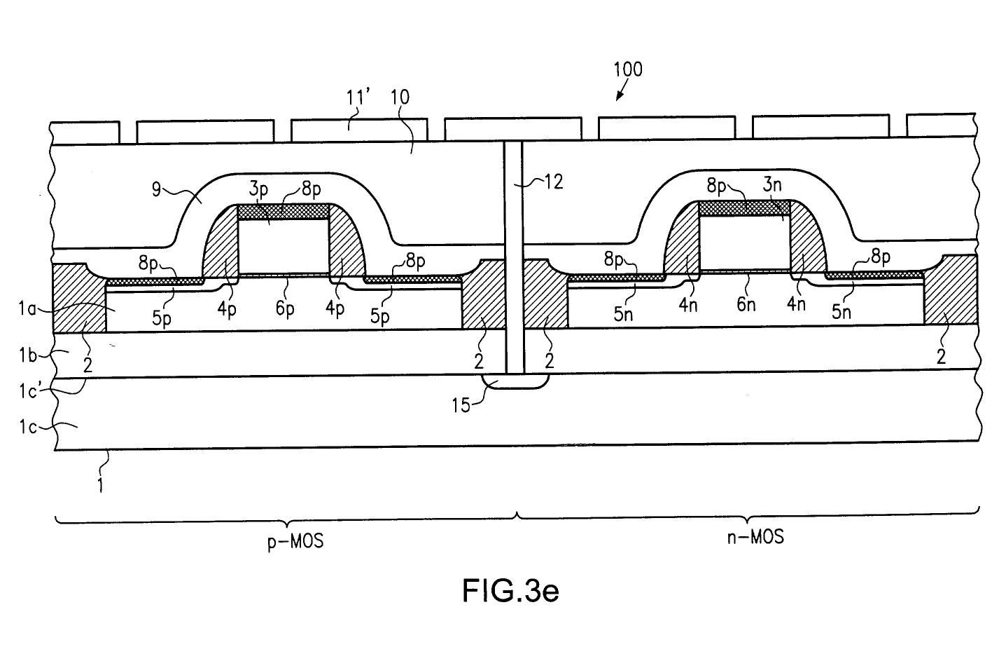

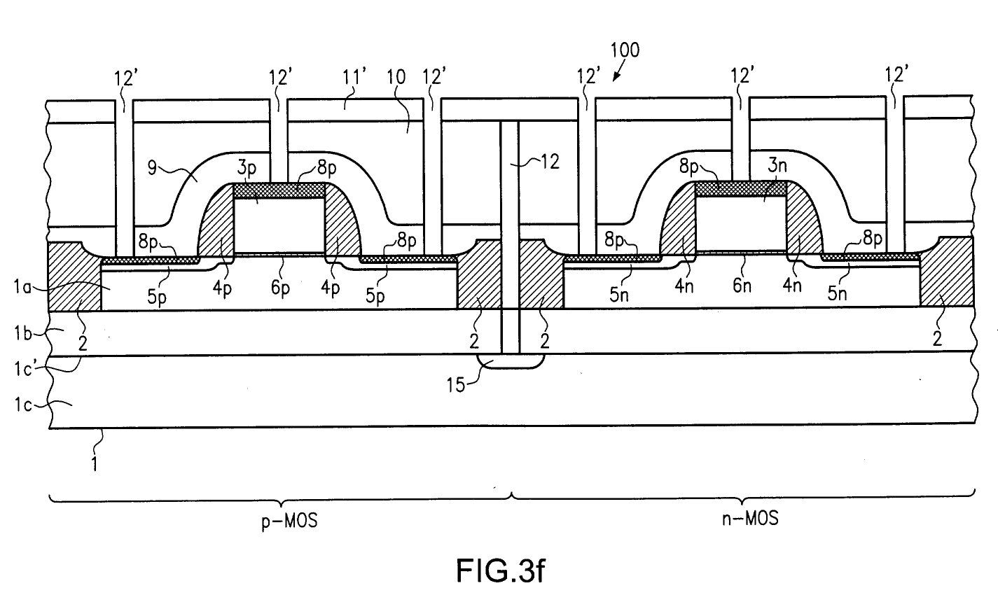

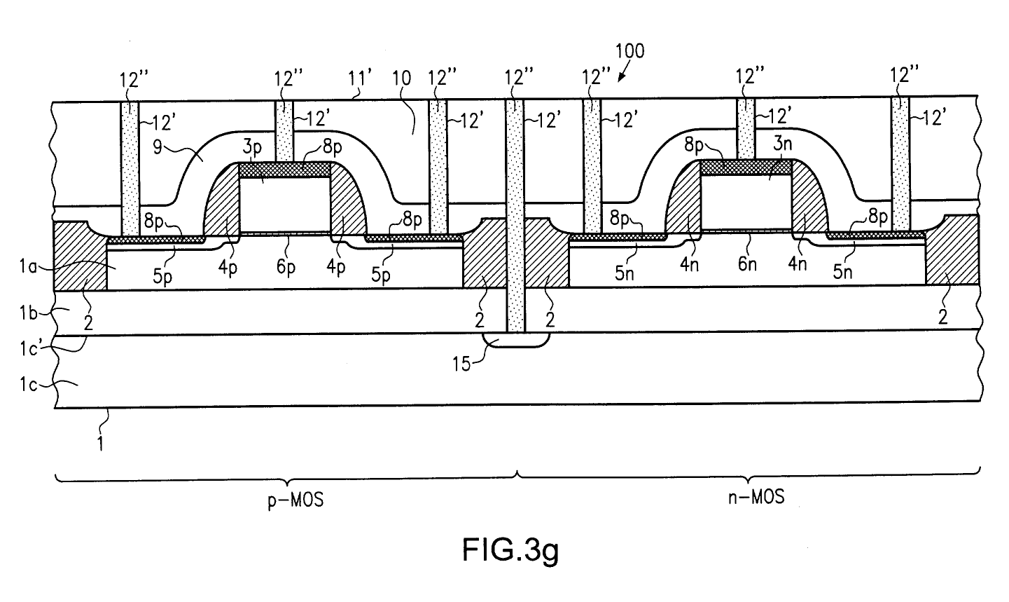

In FIGS. 2a-2g and 3a-3g, the features already described with reference to FIGS. 1a-1g are identified by the same reference numerals. In FIGS. 2a-2g and 3a-3b, reference 1 relates to an arbitrary section of an SOI wafer, for instance a silicon-on-sapphire (SOS) wafer, on which a CMOS transistor 100 is to be formed. In particular, in the figures, the SOI wafer is depicted as comprising an upper and a lower silicon layer 1a and 1c, respectively, as well as a dielectric layer 1b sandwiched therebetween. Reference 2 relates to isolation structures (for instance STI structures) formed according to processes well known to those skilled in the art. The isolation structures 2 divide the upper silicon layer 1a of the SOI substrate 1 into two portions, namely a PMOS portion and an NMOS portion on which the PMOS transistor and the NMOS transistor have to be formed, respectively. In the specific case depicted in FIGS. 2a-2g and 3a-3b, the PMOS portion is depicted on the left side of the figures, while the NMOS portion is depicted on the right side. Moreover, the isolation structures 2 usually comprise an isolating material such as silicon oxide or the like. In FIGS. 2a-2g and 3a-3g, references 3p and 3n relate to the polysilicon gate electrodes, afterwards also referred to as gate polysilicon lines, formed on the PMOS portion and the NMOS portion, respectively. References 6p and 6n relate to the gate insulation layers formed on the PMOS portion and the NMOS portion. Additionally, references 5p and 5n relate to the source and drain regions, while references 4p and 4n relate to sidewall spacers formed on the PMOS and NMOS region, respectively. References 8p and 8n relate to metal suicide layers formed on the gate electrodes and the source and drain regions. Furthermore, reference 13 relates to a nitride layer deposited on the SOI wafer 1 for the purpose of forming the STI structures 2. Reference 15 relates to a heavily doped region formed at the upper surface of the lower silicon layer 1c. References 9 and 10 relate to dielectric planarization layers. References 12, 12′ and 12″ relate to contact holes and metal contacts provided for contacting both the transistor and the heavily doped region 15 in the lower silicon layer 1c of the SOI wafer 1. Reference 13 relates to a layer of silicon nitride deposited on the wafer 1 during the formation of the STI structures. Finally, references 11, 11′ and 13′ relate to resist layers deposited on the wafer during the manufacturing process described below.

The present invention is based on the consideration that metal silicon contacts exhibiting a nearly ohmic behavior can be formed by doping the surface of the lower layer of silicon 1c, for instance by implanting boron ions when the lower layer 1c is formed of a pre-doped P-type substrate. If the lower layer 1c is formed of a pre-doped N-type substrate, the lower layer 1c may be doped with phosphorous ions.

Accordingly, as will be explained in more detail in the following, the illustrative embodiments of the present invention for forming backside contacts on SOI wafers comprise the formation of a heavily doped region in the surface of the lower silicon layer 1c of the SOI substrate during manufacturing of the devices on the wafer. Once the devices have been completed and the wafer planarized, a contact is formed from the upper surface of the wafer to the heavily doped region. Since the heavily doped region is contacted, the contact does not exhibit a Schottky behavior, but instead exhibits nearly ohmic characteristics. Accordingly, the backside of the wafer is conveniently contacted and the performance of the devices on the wafer is not negatively influenced.

The heavily doped region at the surface 1c′ of the lower silicon layer 1c of the SOI wafer is formed during manufacturing of the devices on the wafer. In particular, in the case of CMOS transistors being manufactured on SOI wafers, the heavily doped region is realized during the formation of the shallow trench isolation structures.

In FIG. 2a there is depicted the situation on an SOI wafer 1 at the moment during the manufacturing process when shallow trench isolation structures are to be formed. Accordingly, in FIG. 2a, references 13 and 13′ relate to a nitride layer and a resist layer, respectively, which have been deposited on the SOI wafer 1. For instance, the nitride layer 13 may be deposited with a low pressure chemical vapor deposition (LPCVD) process. Alternatively, a thin pad oxide (not depicted in the figures) can be grown first, and the LPCVD nitride layer 13 can be deposited thereon afterwards. However, the dielectric layer 13 and, eventually, the pad oxide layer are formed for masking purposes only. Whether two superimposed layers or just one silicon nitride layer (as depicted in FIG. 2a) are formed is not essential to the present invention and will accordingly not be disclosed in greater detail.

As apparent from FIG. 2a, the resist layer 13′ has been patterned during an exposing and developing step so as to expose those portions of the nitride layer 13 vertically corresponding to those portions of the upper silicon layer 1a which are targeted for the STI isolation structures. Subsequently, as depicted in FIG. 2b, the exposed portions of the nitride layer 13 are etched away; for instance, a dry anisotropic etching step well known in the art can be performed for etching the exposed portions of the nitride layer 13.

Once the exposed portions of the nitride layer 13 have been etched, the corresponding exposed portions of the upper silicon layer 1a are etched so as to form trenches 13″ into the upper silicon layer 1a of the SOI wafer 1 (see FIG. 2c). This may be accomplished by performing a second anisotropic etching step. Depending on the circumstances, the exposed portions of the upper silicon layer 1a can be completely removed (as depicted in FIG. 2c) so as to expose corresponding portions of the underlying dielectric layer lb. Alternatively, the trenches 13″ can be etched to a depth which is less than the thickness of the upper silicon layer 1a.

After the trenches 13″ have been opened, a further resist layer 14 is deposited on the wafer 1 and patterned as depicted in FIG. 2d. In particular, as apparent from FIG. 2d, the resist layer 14 is patterned so as to expose that portion of the dielectric layer 1b vertically corresponding to the position in the lower silicon layer 1c where the heavily doped region 15 (see FIG. 2f) will be formed. The size of the opening 14′ in the resist layer 14 above the area where the doped region 15 will be formed may vary. In one illustrative example, the opening 14′ may have a generally circular cross-section.

During a next step, as depicted in FIG. 2e, dopants are implanted through the patterned resist layer 14 and the buried dielectric layer 1b to increase the doping of the region 15 of the lower silicon layer 1c vertically corresponding to the exposed portion of the buried oxide layer 1b. Typical implantation parameters are approximately 60-100 keV at a dose of approximately 5×10¹⁴−5×10¹⁵ atoms/cm² for boron ions, and approximately 160-200 keV at a dose of approximately 5×10¹⁴−5×10¹⁵ atoms/cm² for phosphorous.

Once the ion implantation step is completed, the resist 14 is removed and the wafer 1 is subjected to a thermal process, allowing the doping material to diffuse into the lower silicon layer 1c so as to form a heavily doped region 15 at the surface of the lower silicon layer 1c (see FIG. 2f).

Later during the manufacturing process, electrical contacts will be formed on the substrate 1. In particular, a contact hole will be opened from the upper surface of the substrate that has been planarized to the heavily doped region 15. To this end, as will become more apparent from the following disclosure, the same mask as used for patterning the resist layer 14 may be used once again for opening this contact hole to the heavily doped region 15.

After the heavily doped region 15 has been formed as illustrated above, the manufacturing processes are carried out in the usual way until the CMOS transistor is completed. In particular, in the next step, the shallow trench isolation structures 2 are formed. To this end, as depicted in FIG. 2g, the trenches 13″ (see FIG. 2c) are filled with a dialectic material, for instance silicon oxide, and the excess silicon oxide and the nitride layer 13 are removed with a polishing process. Depending on the circumstances, a thin thermal oxide (not depicted in the figures) can be grown on the trench walls before filling the trenches 13″ with silicon oxide.

Subsequently, the manufacturing process is continued until the CMOS transistor is completed and the contacts to the transistor and to the backside of the wafer must be formed. The manufacturing steps for completing the CMOS transistor do not belong to the present invention and do not need to be described in detail, accordingly; instead the disclosure proceeds with the formation of the contacts.

FIG. 3a depicts the manufacturing process at the stage when contacts must be formed (similar to FIG. 1a). Several known approaches can be used for the purpose of forming the contacts on the wafer 1. For example, the dual-contact approach as described with reference to FIGS. 1a-1g can be used. However, in view of the fact that the heavily doped region 15 has been formed in the lower silicon layer 1c, using the dual-contact approach will not result in a Schottky backside contact being formed, but a nearly ohmic contact will be formed, as apparent from the following disclosure.

As explained with reference to FIGS. 2a-2g, the dual-contact approach for forming contacts on SOI wafers begins with the planarization of the wafer. To this end, as depicted in FIG. 3b, a dielectric stack is formed on the wafer 1. In particular, the dielectric stack comprises a first dielectric layer 9 and a second dielectric layer 10, which is planarized after deposition by chemical mechanical polishing (CMP).

After planarization of the dielectric layer 10, a first masking and etching step is used to open a contact hole from the upper surface of the planarized wafer to the heavily doped region 15. In particular, as apparent from FIG. 3c, a first resist layer 11 is deposited and patterned. Thereafter, the exposed dielectric layer 10, the underlying dielectric layer 9 as well as the isolation structures 2, and the dielectric layer 16 are etched so as to form a contact hole 12 from the upper surface of the wafer 1 to the heavily doped region 15.

Once the contact hole 12 has been formed, contact holes 12′ are opened during a further masking and etching step, as depicted in FIGS. 3e and 3f, from the upper surface of the wafer to the PMOS and NMOS transistors. Finally, all contact holes are filled with tungsten 12″ in a common fill step as depicted in FIG. 1g and the excess tungsten 12″ is removed from the wafer during a CMP step not depicted in the figures. For further details concerning the opening of the contact holes 12 and 12′, as well as the filling of the contact holes, reference can be made to the disclosure given above with reference to FIGS. 1a-1g.

As a final result, the backside contact exhibits nearly ohmic characteristics due to the heavily doped region 15 that is provided in the lower silicon layer 1c.

In conclusion, the present invention allows the realization of backside contacts that do not show the drawbacks affecting the contacts formed according to the prior art methods. In particular, the performance of the devices manufactured on SOI wafers are not negatively affected by the contacts provided according to the method of the present invention.

Furthermore, the embodiments relating to methods for forming backside contacts on SOI wafers may be readily implemented in existing manufacturing process flows without adding costs and/or complexity. In particular, the same mask used for implanting the heavily doped region in the lower silicon oxide layer can be used for opening the backside contact hole.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming at least one electrical contact on a substrate, wherein the substrate comprises an upper and a lower semiconductor layer and a dielectric layer sandwiched therebetween, the method comprising:
masking the substrate with a first protective layer comprising at least one aperture;
implanting a dopant material into the lower semiconductor layer through the at least one aperture of the protective layer so as to form at least one doped region in the lower semiconductor layer in correspondence with the at least one aperture of the protective layer; and
forming at least one conductive via that extends from the at least one doped region in the lower semiconductor layer to the upper surface of the substrate.

2. The method as claimed in claim 1, wherein masking the substrate comprises depositing a first layer of protective resist on the upper semiconductor layer, exposing the first layer of resist using a first exposing mask and developing the resist so as to form the at least one aperture.

3. The method as claimed in claim 2, further comprising removing the first resist layer after implanting said dopant material and subjecting the substrate to a thermal process allowing the dopant material to diffuse into the lower semiconductor layer so as to further form the at least one doped region.

4. The method as claimed in claim 3, wherein forming the at least one conductive via comprises masking the substrate with a second protective layer comprising at least one aperture in correspondence with the at least one doped region and etching the at least one exposed portion of the substrate in correspondence with the at least one aperture so as to form at least one hole through the upper semiconductor layer and the sandwiched dielectric layer to the at least one doped region.

5. The method as claimed in claim 4, further comprising filling the at least one hole with a conductive material.

6. The method as claimed in claim 5, wherein masking the substrate with the second protective layer comprises depositing a second layer of protective resist on the upper semiconductor layer, exposing the second layer of protective resist using the first exposing mask and developing the resist so as to form the at least one aperture.

7. The method as claimed in claim 6, wherein etching the at least one exposed portion of the substrate comprises dry etching the upper semiconductor layer and the sandwiched dielectric layer.

8. The method as claimed in claim 7, wherein the at least one hole is filled with tungsten.

9. The method as claimed in claim 8, wherein one of boron and phosphorous is used as a dopant.

10. The method as claimed in claim 9, wherein the top and bottom semiconductor layers comprise silicon.

11. The method as claimed in claim 10, wherein the dielectric layer comprises silicon oxide.

12. The method as claimed in claim 11, further comprising removing the excess conductive material with a chemical mechanical polishing process.

13. A method of forming at least one semiconductor device on a substrate, wherein the substrate comprises an upper and a lower semiconductor layer and a first dielectric layer sandwiched therebetween, the method comprising:
doping the lower semiconductor layer with a dopant material so as to form at least one doped region in the lower semiconductor layer;
completing the at least one semiconductor device;
depositing at least one second layer of dielectric material above the upper semiconductor layer;
planarizing the second layer of dielectric material; and
forming at least one conductive via that extends through the planarized dielectric material, the upper semiconductor layer and the sandwiched dielectric layer to the at least one doped region in the lower semiconductor layer.

14. The method as claimed in claim 13, wherein doping the lower semiconductor layer comprises masking the substrate with a first protective layer comprising at least one aperture and implanting a dopant material into the lower semiconductor layer through the at least one aperture of the protective layer so as to form at least one doped region in the lower semiconductor layer in correspondence with the at least one aperture of the protective layer.

15. The method as claimed in claim 14, wherein masking the substrate comprises depositing a first layer of protective resist on the upper surface of the upper semiconductor layer, exposing the first resist layer using a first exposing mask and developing the resist so as to form the at least one aperture.

16. The method as claimed in claim 15, further comprising removing the first resist layer after implanting the dopant material and subjecting the substrate to a thermal process allowing the dopant material to diffuse into the lower semiconductor layer so as to further form the at least one doped region.

17. The method as claimed in claim 16, wherein forming the at least one conductive via comprises masking the substrate with a second protective layer comprising at least one aperture in correspondence with the at least one doped region and etching the at least one exposed portion of the substrate in correspondence with the at least one aperture so as to form at least one hole through the dielectric planarizing layer, the upper semiconductor layer and the sandwiched dielectric layer to the at least one doped region.

18. The method as claimed in claim 17, further comprising filling the at least one hole with a conductive material.

19. The method as claimed in claim 18, wherein masking the substrate with the second protective layer comprises depositing a second layer of protective resist on the dielectric planarizing layer, exposing the second layer of protective resist by using the first exposing mask and developing the resist so as to form the at least one aperture.

20. The method as claimed in claim 19, wherein etching the at least one exposed portion of the substrate comprises dry etching the dielectric planarizing layer, the upper semiconductor layer and the sandwiched dielectric layer.

21. The method as claimed in claim 20, wherein the at least one hole is filled with tungsten.

22. The method as claimed in claim 21, wherein one of boron and phosphorous is used as a dopant.

23. The method as claimed in claim 22, wherein the top and bottom semiconductor layers comprise silicon.

24. The method as claimed in claim 23, wherein the sandwiched dielectric layer comprises silicon oxide.

25. The method as claimed in claim 24, wherein the dielectric planarizing layer comprises an underlying layer of SiON and an overlying layer of silicon oxide.

26. The method as claimed in claim 25, further comprising removing the excess conductive material with a chemical mechanical polishing process.

27. A method of forming at least one field effect transistor on a substrate, wherein the substrate comprises an upper and a lower semiconductor layer and a dielectric layer sandwiched therebetween, the method comprising:
forming at least one doped region at the upper surface of the lower semiconductor layer;
completing the at least one field effect transistor and depositing at least one dielectric planarization layer on the substrate; and
forming at least one contacting via from the upper surface of the at least one dielectric planarization layer to the at least one doped region and at least one conductive via from the upper surface of the at least one dielectric planarization layer to the at least one field effect transistor.

28. The method as claimed in claim 27, wherein forming the at least one doped region comprises masking the substrate with a first protective layer comprising at least one aperture and implanting a dopant material into the lower semiconductor layer through the at least one aperture of the protective layer so as to form at least one doped region in the lower semiconductor layer in correspondence with the at least one aperture of the protective layer.

29. The method as claimed in claim 28, wherein masking the substrate comprises depositing a first layer of protective resist on the upper surface of the substrate, exposing the first resist layer using a first exposing mask and developing the resist so as to form the at least one aperture.

30. The method as claimed in claim 29, further comprising removing the first resist layer after implanting the dopant material and subjecting the substrate to a thermal process allowing the dopant material to diffuse into the lower semiconductor layer so as to further form the at least one doped region.

31. The method as claimed in claim 30, wherein forming the at least one conductive via from the upper surface of the at least one dielectric planarization layer to the at least one doped region comprises masking the substrate with a second protective layer comprising at least one aperture in correspondence with the at least one doped region and etching the at least one exposed portion of the substrate in correspondence with the at least one aperture so as to form at least one hole through the at least one dielectric planarization layer, the upper semiconductor layer and the sandwiched dielectric layer to the at least one doped region.

32. The method as claimed in claim 31, wherein masking the substrate with the second protective layer comprises depositing a second layer of protective resist on the at least one dielectric planarizing layer, exposing the second layer of protective resist by using the first exposing mask and developing the resist so as to form the at least one aperture.

33. The method as claimed in claim 32, wherein etching the at least one exposed portion of the substrate comprises dry etching the at least one dielectric planarization layer, the upper semiconductor layer and the sandwiched dielectric layer.

34. The method as claimed in claim 29, wherein forming the at least one conductive via from the upper surface of the at least one dielectric planarization layer to the at least one field effect transistor comprises masking the substrate with a third protective layer having at least one aperture in correspondence with the at least one field effect transistor and etching the at least one exposed portion of the substrate in correspondence with the at least one aperture so as to form at least one hole through the at least one dielectric planarization layer, from the upper surface of the at least one dielectric planarization layer to the at least one field effect transistor.

35. The method as claimed in claim 34, wherein masking the substrate with a third protective layer comprises depositing a third layer of protective resist, exposing the resist by using a second exposing mask and developing the resist so as to form the at least one aperture in correspondence with the at least one field effect transistor.

36. The method as claimed in claim 35, further comprising filling the at least one hole from the upper surface of the dielectric planarization layer to the at least one doped region and the at least one hole from the upper surface of the dielectric planarization layer to the at least one field effect transistor with a conductive material.

37. The method as claimed in claim 36, wherein the filling conductive material comprises tungsten.

38. The method as claimed in claim 37, further comprising removing the excess conductive material with a chemical mechanical polishing process.

39. The method as claimed in claim 28, wherein the dopant material comprises one of boron and phosphorous.

40. The method as claimed in claim 39, further comprising depositing a first and a second dielectric planarization layers and polishing the second planarization layer.

41. The method as claimed in claim 40, wherein etching the holes from the upper surface of the planarization layer to the at least one doped region and to the at least one field effect transistor comprises dry etching.

42. The method as claimed in claim 41, wherein the upper semiconductor layer comprises silicon.

43. The method as claimed in claim 42, wherein the sandwiched dielectric layer comprises silicon oxide.

44. The method as clamed in claim 43, wherein the lower semiconductor layer comprises silicon.

45. A method of forming at least one field effect transistor on a substrate, wherein the substrate comprises an upper and a lower semiconductor layer and a dielectric layer sandwiched therebetween, the method comprising:
forming a plurality of features above the upper semiconductor layer, said features defining at least one trench above the upper semiconductor layer;
forming at least one doped region in a portion of the lower semiconductor layer underneath the at least one trench above the upper semiconductor layer;
completing the at least one field effect transistor;
depositing at least one dielectric layer above the substrate;
planarizing the dielectric layer; and
forming at least one contacting via that extends from an upper surface of the planarized dielectric layer to the at least one doped region and at least one conductive via that extends from the upper surface of the planarized dielectric layer to the at least one field effect transistor.

46. The method as claimed in claim 45, wherein forming the at least one trench on the upper semiconductor layer comprises masking the substrate with a first protective layer comprising at least one aperture and etching the at least one exposed portion of the upper semiconductor layer in correspondence with the at least one aperture of the first protective layer.

47. The method as claimed in claim 46, wherein masking the substrate with a first protective layer comprising at least one aperture comprises depositing a layer of silicon nitride on the upper semiconductor layer, masking the layer of silicon nitride with a second protective layer comprising at least one aperture and etching the at least one exposed portion of the layer of silicon nitride in correspondence with the at least one aperture.

48. The method as claimed in claim 47, wherein masking the layer of silicon nitride with a second protective layer comprises depositing a first layer of a protective resist, exposing the resist by using a first exposing mask and developing the resist.

49. The method as claimed in claim 48, wherein forming the at least one doped region comprises masking the substrate with a third protective layer comprising at least one aperture in correspondence with the at least one trench above the upper semiconductor layer and implanting a dopant material into the lower semiconductor layer through the at least one aperture of the third protective layer.

50. The method as claimed in claim 49, wherein masking the substrate with a third protective layer comprises depositing a second layer of protective resist on the substrate, exposing the second layer of protective resist by using a second exposing mask and developing the resist so as to form the at least one aperture in correspondence with the at least one trench on the upper semiconductor layer.

51. The method as claimed in claim 50, further comprising removing the second layer of resist after implanting said dopant material and subjecting the substrate to a thermal process allowing the dopant material to diffuse into the lower semiconductor layer so as to further form the at least one doped region.

52. The method as claimed in claim 51, further comprising filling the at least one trench above the upper semiconductor layer with a dielectric material.

53. The method as claimed in claim 52, wherein the at least one trench is filled by depositing silicon oxide according to a chemical vapor deposition process, and wherein the excess silicon oxide and the silicon nitride on the upper semiconductor layer are removed.

54. The method as claimed in claim 53, wherein forming the at least one conductive via from the upper surface of the at least one dielectric planarization layer to the at least one doped region comprises masking the substrate with a fourth protective layer comprising at least one aperture in correspondence with the at least one doped region and etching the at least one exposed portion of the substrate so as to form at least one hole through the at least one dielectric planarization layer, the deposited silicon oxide and the sandwiched dielectric layer.

55. The method as claimed in claim 54, wherein masking the substrate with the fourth protective layer comprises depositing a third layer of protective resist on the at least one dielectric planarization layer, exposing the third layer of resist by using the second exposing mask and developing the resist so as to form the at least one aperture.

56. The method as claimed in claim 55, wherein etching the at least one exposed portion of the substrate comprises dry etching the at least one dielectric planarization layer, the underlying deposited silicon oxide and the sandwiched dielectric layer.

57. The method as claimed in claim 56, wherein forming the at least one conductive via from the upper surface of the at least one dielectric planarization layer to the at least one field effect transistor comprises masking the substrate with a fifth protective layer having at least one aperture in correspondence with the at least one field effect transistor and etching the at least one exposed portion of the substrate in correspondence with the at least one aperture so as to form at least one hole through the at least one dielectric planarization layer.

58. The method as claimed in claim 57, wherein masking the substrate with a fifth protective layer comprises depositing a fourth layer of protective resist, exposing the resist by using a third exposing mask and developing the resist so as to form the at least one aperture in correspondence with the at least one field effect transistor.

59. The method as claimed in claim 58, further comprising filling the at least one hole from the upper surface of the dielectric planarization layer to the at least one doped region of decreased resistance and the at least one hole from the upper surface of the dielectric planarization layer to the at least one field effect transistor with a conductive material.

60. The method as claimed in claim 59, wherein the holes are filled during a common filling step.

61. The method as claimed in claim 60, wherein the filling conductive material comprises tungsten.

62. The method as claimed in claim 61, further comprising removing the excess conductive material with a chemical mechanical polishing process.

63. The method as claimed in claim 62, wherein the dopant material comprises one of boron and phosphorous.

64. The method as claimed in claim 63, further comprising depositing two dielectric planarization layers and polishing the upper planarization layer.

65. The method as claimed in claim 64, wherein etching the holes from the upper surface of the planarization layer to the at least one doped region and to the at least one field effect transistor comprises dry etching.

66. The method as claimed in claim 65, wherein the upper semiconductor layer comprises silicon.

67. The method as claimed in claim 66, wherein the sandwiched dielectric layer comprises silicon oxide.

68. The method as claimed in claim 67, wherein the lower semiconductor layer comprises silicon.

69. The method as claimed in claim 68, wherein the at least one field effect transistor is a CMOS transistor.

70. The method as claimed in claim 69, wherein forming the at least one trench comprises etching the upper semiconductor layer so as to expose at least one portion of the sandwiched dielectric layer.

71. A field effect transistor formed on a substrate, wherein the substrate comprises at least an upper and a lower semiconductor layer and a dielectric layer sandwiched therebetween, the transistor comprising:
at least one doped region in the lower semiconductor layer; and
at least one electrical contact contacting the at least one region of decreased resistance.

72. The field effect transistor as claimed in claim 71, further comprising at least one planarizing dielectric layer, and wherein the at least one contact comprises a conductive via from the upper surface of the at least one dielectric planarizing layer to the at least one doped region.

73. The field effect transistor as claimed in claim 72, wherein the at least one conductive via comprises a contact hole filled with at least one conductive material.

74. The field effect transistor as claimed in claim 73, wherein the at least one conductive material comprises tungsten.

75. The field effect transistor as claimed in claim 74, wherein the at least one region of decreased resistance comprises at least one dopant at a concentration of 10¹⁹-10²¹ atoms/cm³.

76. The field effect transistor as claimed in claim 75, wherein the at least one dopant comprises one of boron and phosphorous.

77. The field effect transistor as claimed in claim 76, wherein the dielectric planarizing layer comprises an underlying layer of SiON and an overlying layer of silicon oxide.

78. The field effect transistor as claimed in claim 77, wherein the sandwiched dielectric layer comprises silicon oxide.

79. The field effect transistor as claimed in claim 78, wherein the upper and lower semiconductor layer comprise silicon.

80. The field effect transistor as claimed in claim 79, wherein the field effect transistor is a CMOS transistor.

81. The field effect transistor as claimed in claim 80, further comprising shallow trench isolation structures formed in the upper silicon layer.

82. The field effect transistor as claimed in claim 81, wherein the at least one conductive via is formed through the overlying and underlying dielectric planarizing layers, the shallow trench isolation structure and the sandwiched dielectric layer.
